(19) United States
(12) Patent Application Publication
(10) Pub. No.: US 2026/0324060 A1
(43) Pub. Date: Oct. 15, 2026

(54) SEMICONDUCTOR DEVICE AND METHOD FOR FABRICATING THEREOF

(71) Applicant: Samsung Electronics Co., Ltd., Suwon-si (KR)

(72) Inventors: Chang Bea PARK, Suwon-si (KR); Ki-Il KIM, Suwon-si (KR); Hyon Wook RA, Suwon-si (KR); Ji Soo OH, Suwon-si (KR); Sang Hyun LEE, Suwon-si (KR); Kyung Yub JEON, Suwon-si (KR)

(73) Assignee: Samsung Electronics Co., Ltd., Suwon-si (KR)

(21) Appl. No.: 19/290,678

(22) Filed: Aug. 5, 2025

(30) Foreign Application Priority Data
Apr. 14, 2025 (KR) 10-2025-0048423

(51) Int. Cl. H10D 84/83; H01L 23/522; H01L 23/528; H01L 23/532; H10D 30/00; H10D 30/01; H10D 30/43; H10D 30/69; H10D 62/10; H10D 62/13; H10D 64/23; H10D 84/01

(52) U.S. Cl. CPC H10D 84/832; H10D 30/43; H10D 30/502; H10D 30/701; H10D 62/121; H10D 62/151; H10D 64/256; H10W 20/42; H10W 20/435; H10W 20/48; H10D 30/014; H10D 30/019; H10D 30/0415; H10D 84/0149; H10W 20/43

(57) ABSTRACT

A semiconductor device may include a source/drain pattern on a substrate, a source/drain contact structure connected to the source/drain pattern, a first interlayer insulating film on the source/drain contact structure, an etching stop film extending along an upper surface of the first interlayer insulating film, a second interlayer insulating film on the etching stop film, and a connection wiring in the first and second interlayer insulating films. The source/drain contact structure may include a source/drain contact portion and a source/drain via portion protruding from the source/drain contact portion. The first interlayer insulating film may cover a side wall of the source/drain via portion. An upper surface of the first interlayer insulating film may be higher than an upper surface of the source/drain via portion. The connection wiring may be in contact with the upper surface of the source/drain via portion.

### CROSS-REFERENCE TO RELATED APPLICATION

This application claims priority from Korean Patent Application No. 10-2025-0048423 filed on Apr. 14, 2025, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor device and method for fabricating thereof.

### 2. Description of the Related Art

As one of scaling technologies for increasing density of a semiconductor device, a multi gate transistor in which a multi-channel active pattern (or a silicon body) having a fin or nanowire shape is formed on a substrate and a gate is formed on a surface of the multi-channel active pattern has been proposed.

Since such a multi gate transistor utilizes a three-dimensional channel, scaling is more easily performed. Further, even if a gate length of the multi gate transistor is not increased, the current control capability may be improved. Furthermore, a SCE (short channel effect) in which potential of a channel region is influenced by a drain voltage may be more effectively limited and/or suppressed.

On the other hand, as a pitch size of semiconductor devices decreases, research may be needed for reducing the electrostatic capacitance between contacts in the semiconductor device and ensuring electrical stability.

### SUMMARY

Aspects of the present disclosure provide a semiconductor device capable of improving element performance and/or reliability.

Aspects of the present disclosure provide a method for fabricating a semiconductor device capable of improving element performance and/or reliability.

According to an embodiment of the present disclosure, a semiconductor device may include a source/drain pattern on a substrate; a source/drain contact structure connected to the source/drain pattern, the source/drain contact structure including a source/drain contact portion and a source/drain via portion, the source/drain contact portion extending in a first direction, and the source/drain via portion protruding from the source/drain contact portion in a second direction; a first interlayer insulating film on the source/drain contact structure and covering a side wall of the source/drain via portion, an upper surface of the first interlayer insulating film being higher than an upper surface of the source/drain via portion; an etching stop film extending along the upper surface of the first interlayer insulating film; a second interlayer insulating film on the etching stop film; and a connection wiring in the first interlayer insulating film and the second interlayer insulating film, the connection wiring being in contact with the upper surface of the source/drain via portion.

According to an embodiment of the present disclosure, a semiconductor device may include a source/drain pattern on a substrate; a source/drain contact structure connected to the source/drain pattern; a first interlayer insulating film on the source/drain contact structure, an upper surface of the first interlayer insulating film being higher than an upper surface of the source/drain contact structure; a second interlayer insulating film on the first interlayer insulating film; an etching stop film between the first interlayer insulating film and the second interlayer insulating film, and the etching stop film extending along the upper surface of the first interlayer insulating film; and a connection wiring in the first interlayer insulating film and the second interlayer insulating film, the connection wiring being in contact with the source/drain contact structure. The connection wiring may include a line portion and a protruding portion. The line portion may extend in a first direction on the first interlayer insulating film. The protruding portion may protrude from the line portion in a second direction. The protruding portion of the connection wiring may be in the first interlayer insulating film and the protruding portion of the connection wiring may be in contact with the upper surface of the source/drain contact structure. The etching stop film may not extend along a boundary between the protruding portion of the connection wiring and the first interlayer insulating film.

According to an embodiment of the present disclosure, a semiconductor device may include a gate electrode extending in a first direction on a substrate; a source/drain pattern on the substrate and disposed on at least one side of the gate electrode; a source/drain contact structure connected to the source/drain pattern, the source/drain contact structure including a source/drain contact portion and a source/drain via portion, the source/drain contact portion extending in the first direction, and the source/drain via portion protruding from the source/drain contact portion in a second direction; a first interlayer insulating film on the source/drain contact structure and covering a side wall of the source/drain via portion, an upper surface of the first interlayer insulating film being higher than an upper surface of the source/drain via portion; a gate contact in the first interlayer insulating film and connected to the gate electrode, an upper surface of the gate contact being higher than an upper surface of the source/drain contact structure; a second interlayer insulating film on the first interlayer insulating film; an etching stop film between the first interlayer insulating film and the second interlayer insulating film, the etching stop film extending along the upper surface of the first interlayer insulating film; and a connection wiring in the first interlayer insulating film and the second interlayer insulating film, the connection wiring being in contact with the upper surface of the source/drain via portion. The connection wiring may include a line portion and a protruding portion. The line portion may extend in a third direction on the first interlayer insulating film. The protruding portion may protrude from the line portion of the connection wiring in the second direction. The protruding portion of the connection wiring may be in the first interlayer insulating film.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail illustrative implementations thereof with reference to the attached drawings, in which:

FIG. 1 is an example layout diagram for explaining the semiconductor device according to some embodiments.

FIG. 2 is a cross-sectional view taken along A-A of FIG. 1.

FIG. 3 is a cross-sectional view taken along B-B of FIG. 1.

FIG. 4 is a cross-sectional view taken along C-C of FIG. 1.

FIGS. 5 and 6 are enlarged views of a portion P of FIG. 4, respectively.

FIGS. 7 and 8 are diagrams for explaining a semiconductor device according to some embodiments.

FIGS. 9 and 10 are diagrams for explaining a semiconductor device according to some embodiments.

FIGS. 11 to 13 are diagrams for explaining a semiconductor device according to some embodiments.

FIGS. 14 and 15 are diagrams for explaining a semiconductor device according to some embodiments.

FIGS. 16 to 19 are diagrams for explaining a semiconductor device according to some embodiments.

FIG. 20 is a diagram for explaining a semiconductor device according to some embodiments.

FIGS. 21 to 40 are intermediate stage diagrams for explaining a method for fabricating a semiconductor device according to some embodiments.

### DETAILED DESCRIPTION

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Although drawings of a semiconductor device according to some embodiments, for example, show a fin-shaped transistor (FinFET) including a channel region of a fin-shaped pattern shape, a transistor including nanowire or nanosheet, and a MBCFET^{TM} (Multi-Bridge Channel Field Effect Transistor), the present disclosure is not limited thereto. The semiconductor device according to some embodiments may, of course, include a tunneling transistor (tunneling FET) or a three-dimensional (3D) transistor. The semiconductor device according to some embodiments may, of course, include a planar transistor. In addition, the technical idea of the present disclosure may be applied to a transistor based on two-dimensional material (2D material based FETs) and a heterostructure thereof.

Further, the semiconductor device according to some embodiments may also include a bipolar junction transistor, a laterally diffused metal oxide semiconductor (LDMOS), or the like.

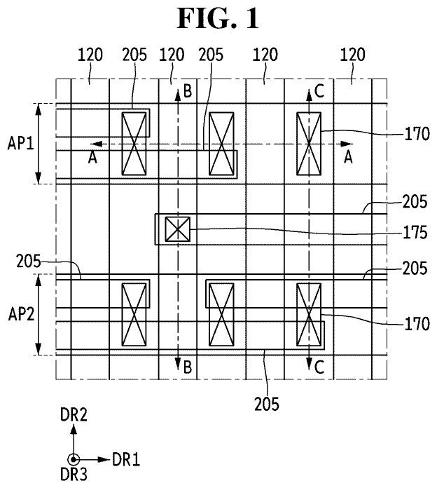

The semiconductor device according to some embodiments will be described referring to FIGS. 1 to 6.

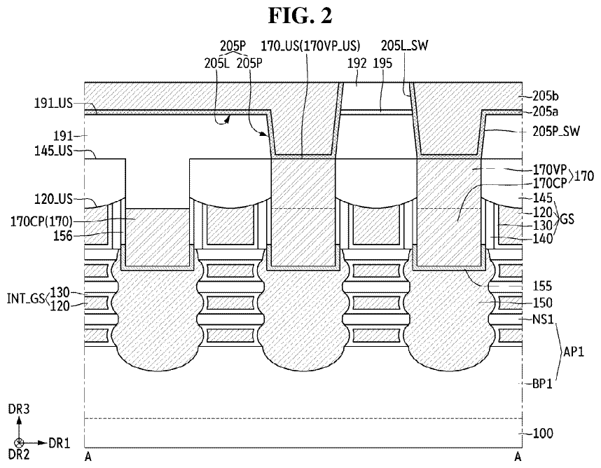

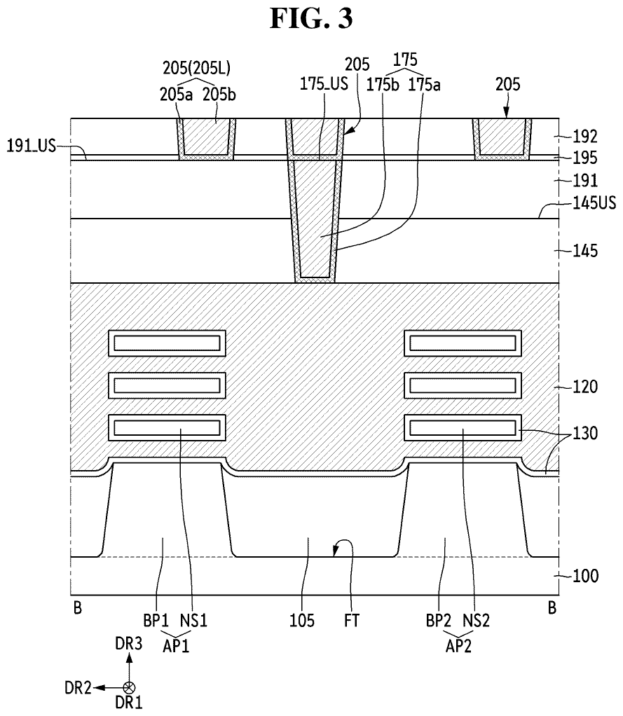

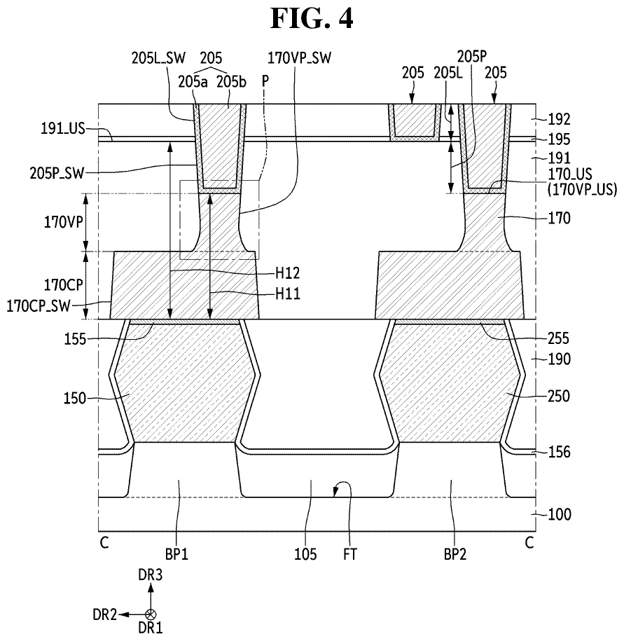

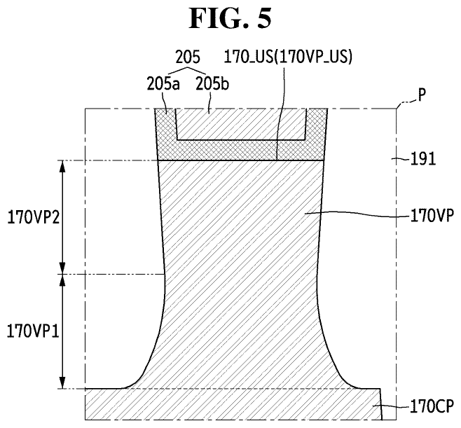

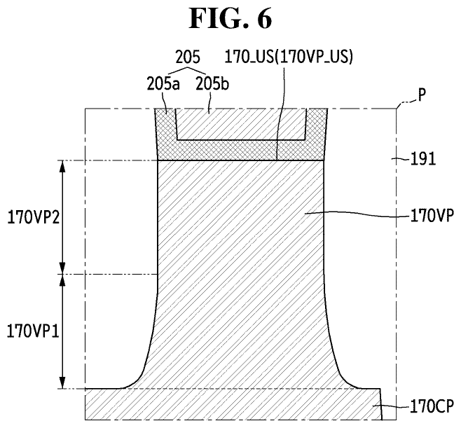

FIG. 1 is an example layout diagram for explaining the semiconductor device according to some embodiments. FIG. 2 is a cross-sectional view taken along A-A of FIG. 1. FIG. 3 is a cross-sectional view taken along B-B of FIG. 1. FIG. 4 is a cross-sectional view taken along C-C of FIG. 1. FIGS. 5 and 6 are enlarged views of a portion P of FIG. 4, respectively.

For convenience of explanation, although a gate contact 175 is shown as being disposed on one first gate electrode 120 among the plurality of first gate electrodes 120, this is only for the purpose of explanation, and the embodiment is not limited thereto.

Referring to FIGS. 1 to 6, the semiconductor device according to some embodiments may include a first active pattern AP1, a second active pattern AP2, at least one or more gate electrodes 120, a source/drain contact structure 170, a gate contact 175, and a connection wiring 205.

As an example, the substrate 100 may be a bulk semiconductor or a semiconductor-on-insulator such as bulk silicon or silicon-on-insulator (SOI). In some embodiments, the substrate 100 may be a silicon substrate, or may include other materials, for example, silicon germanium, silicon germanium on insulator (SGOI), indium antimonide, lead telluride, indium arsenide, indium phosphide, gallium arsenide or gallium antimonide. As another example, the substrate 100 may be formed of an insulating material.

The first active pattern AP1 and the second active pattern AP2 may be disposed on the substrate 100. Each of the first active pattern AP1 and the second active pattern AP2 may extend long in a first direction DR1. The first active pattern AP1 and the second active pattern AP2 may be spaced apart from each other in a second direction DR2. For example, the first direction DR1 may be a direction that intersects the second direction DR2.

As an example, one of the first active pattern AP1 and the second active pattern AP2 may be a PMOS formation region, and the other thereof may be an NMOS formation region. As another example, the first active pattern AP1 and the second active pattern AP2 may be an NMOS formation region. As yet another example, the first active pattern AP1 and the second active pattern AP2 may be a PMOS formation region. In other words, the first active pattern AP1 and the second active pattern AP2 may be formation regions of a same type or formation regions of different types.

As an example, the first active pattern AP1 and the second active pattern AP2 may be disposed in a logic region. As another example, the first active pattern AP1 and the second active pattern AP2 may be disposed in an SRAM region. As yet another example, the first active pattern AP1 and the second active pattern AP2 may be disposed in an I/O region.

The first active pattern AP1 and the second active pattern AP2 may be, for example, a multi-channel active pattern. The first active pattern AP1 may include a first lower pattern BP1 and a plurality of first sheet patterns NS1. The second active pattern AP2 may include a second lower pattern BP2 and a plurality of second sheet patterns NS2.

Each of the first lower pattern BP1 and the second lower pattern BP2 may protrude from the substrate 100. Each of the first lower pattern BP1 and the second lower pattern BP2 may extend long in the first direction DR1.

The first lower pattern BP1 may be spaced apart from the second lower pattern BP2 in the second direction DR2. The first lower pattern BP1 and the second lower pattern BP2 may be separated by a fin trench FT extending in the first direction DR1.

The plurality of first sheet patterns NS1 may be disposed on an upper surface of the first lower pattern BP1. The plurality of first sheet patterns NS1 may be spaced apart from the first lower pattern BP1 in a third direction DR3. Each of the first sheet patterns NS1 may be spaced apart in from each other in the third direction DR3. The third direction DR3 may be a direction that intersects the first direction DR1 and the second direction DR2. For example, the third direction DR3 may be a thickness direction of the substrate 100.

The plurality of second sheet patterns NS2 may be disposed on the upper surface of the second lower pattern BP2. The plurality of second sheet patterns NS2 may be spaced apart from the second lower pattern BP2 in the third direction DR3. Each second sheet pattern NS2 may be spaced apart from each other in the third direction DR3.

Although each of the three first sheet patterns NS1 and the three second sheet patterns NS2 is shown as being disposed in the third direction DR3, this is only for convenience of explanation, and the embodiment is not limited thereto.

As an example, the first lower pattern BP1 and the second lower pattern BP2 may be formed by etching a part of the substrate 100, and/or may include an epitaxial layer grown from the substrate 100. Each of the first lower pattern BP1 and the second lower pattern BP2 may include silicon or germanium, which are elemental semiconductor materials. In addition or alternatively, the first lower pattern BP1 and the second lower pattern BP2 may include a compound semiconductor, and may include, for example, a group IV-IV compound semiconductor or a group III-V compound semiconductor.

The group IV-IV compound semiconductor may include, for example, a binary compound or a ternary compound including at least two or more of carbon (C), silicon (Si), germanium (Ge) and tin (Sn), or a compound obtained by doping these elements with a group IV element.

The group III-V compound semiconductor may be, for example, at least one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

As another example, the first lower pattern BP1 and the second lower pattern BP2 may be formed by filling a space, from which a pattern including a semiconductor material is removed, with an insulating material. Each of the first lower pattern BP1 and the second lower pattern BP2 may include an insulating material.

Each of the first sheet pattern NS1 and the second sheet pattern NS2 may include one of silicon or germanium which is an elemental semiconductor material, a group IV-IV compound semiconductor or a group III-V compound semiconductor. When the first lower pattern BP1 includes a semiconductor material, the first sheet pattern NS1 may include the same material as the first lower pattern BP1, and may include a different material from the first lower pattern BP1. Similarly, when the second lower pattern BP2 includes a semiconductor material, the second sheet pattern NS2 may include the same material as the second lower pattern BP2, and may include a different material from the second lower pattern BP2.

In the semiconductor device according to some embodiments, the first lower pattern BP1 and the second lower pattern BP2 may be silicon lower patterns including silicon, and the first sheet pattern NS1 and the second sheet pattern NS2 may be silicon sheet patterns including silicon.

For example, a width of the first sheet pattern NS1 in the second direction DR2 may increase or decrease in proportion to a width of the first lower pattern BP1 in the second direction DR2. As an example, although the widths in the second direction DR2 of the first sheet patterns NS1 stacked in the third direction DR3 are shown as being the same, this is only for convenience of explanation, and the embodiment is not limited thereto. Unlike the shown example, the widths in the second direction DR2 of the first sheet patterns NS1 stacked in the third direction DR3 may decrease as they goes away from the first lower pattern BP1.

A field insulating film 105 may be disposed on the substrate 100. The field insulating film 105 may fill at least a part of the fin trench FT.

The field insulating film 105 may be disposed on the side wall of the first lower pattern BP1 and the side wall of the second lower pattern BP2. The field insulating film 105 is not disposed on the upper surface of the first lower pattern BP1 and the upper surface of the second lower pattern BP2.

As an example, the field insulating film 105 may entirely cover the side wall of the first lower pattern BP1. Unlike the shown example, the field insulating film 105 may cover a part of the side wall of the first lower pattern BP1 and/or a part of the side wall of the second lower pattern BP2. In this case, taking the first lower pattern BP1 as an example, a part of the first lower pattern BP1 may protrude from the upper surface of the field insulating film 105 in the third direction DR3.

The field insulating film 105 may include an upper surface and a bottom surface that are opposite to each other in the third direction DR3. The upper surface of the field insulating film 105 may face the connection wiring 205.

Each of the first sheet patterns NS1 and each of the second sheet patterns NS2 are disposed to be higher than the upper surface of the field insulating film 105. The field insulating film 105 may include, for example, an oxide film, a nitride film, an oxynitride film or a combined film thereof. Although the field insulating film 105 is shown as being a single film, this is only for convenience of explanation, and the embodiment is not limited thereto.

At least one or more gate structures GS may be disposed on the substrate 100. For example, at least one or more gate structures GS may be disposed on the field insulating film 105. The gate structure GS may extend in the second direction DR2. Adjacent gate structures GS may be spaced apart in the first direction DR1.

The gate structure GS may be disposed on the first active pattern AP1 and the second active pattern AP2. The gate structure GS may intersect the first active pattern AP1 and the second active pattern AP2.

Although the gate structure GS is shown as being disposed over the first active pattern AP1 and the second active pattern AP2, this is only for convenience of explanation, and the embodiment is not limited thereto. That is, a part of the gate structure GS may be separated into two portions, and disposed on the first active pattern AP1 and the second active pattern AP2.

The gate structure GS may intersect the first lower pattern BP1 and the second lower pattern BP2. The gate structure GS may enclose the first sheet pattern NS1 and the second sheet pattern NS2.

The gate structure GS may include a gate electrode 120, a gate insulating film 130, a gate spacer 140, and a gate capping pattern 145.

The gate structure GS may include an inner gate structure INT_GS disposed between the first sheet patterns NS1 adjacent to each other in the third direction DR3, and between the first lower pattern BP1 and the first sheet pattern NS1. The inner gate structure INT_GS may include a first gate electrode 120 and a first gate insulating film 130 disposed between the adjacent first sheet patterns NS1, and between the first lower pattern BP1 and the first sheet pattern NS1. Although not shown, the inner gate structure INT_GS may be disposed between the second sheet patterns NS2 adjacent to each other in the third direction DR3, and between the second lower pattern BP2 and the second sheet pattern NS2.

The gate electrode 120 may be disposed on the first lower pattern BP1 and the second lower pattern BP2. The gate electrode 120 may intersect the first lower pattern BP1 and the second lower pattern BP2. The gate electrode 120 may enclose the first sheet pattern NS1. The gate electrode 120 may enclose the second sheet pattern NS2.

An upper surface 120_US of the gate electrode may be, but is not limited to, a concave curved face recessed toward the upper surface of the first active pattern AP1. That is, unlike the shown example, the upper surface 120_US of the gate electrode may be a flat plane. For example, the upper surface of the first active pattern AP1 may be the upper surface of the first sheet pattern NS1 disposed on the uppermost part of the first sheet patterns NS1.

The gate electrode 120 may include a conductive material. For example, the gate electrode 120 may include at least one of a metal, a conductive metal nitride, a metal silicide, a doped semiconductor material, a conductive metal carbonitride, a conductive metal carbide, a conductive metal oxide or a conductive metal oxynitride. The gate electrode 120 may include, for example, but is not limited to at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) or combinations thereof. The conductive metal oxide and the conductive metal oxynitride may include, but are not limited to, an oxidized form of the aforementioned materials.

The gate electrode 120 may be disposed on both sides of a first source/drain pattern 150 to be described below. The gate structure GS may be disposed on both sides of the first source/drain pattern 150 in the first direction DR1.

As an example, all the gate electrodes 120 disposed on both sides of the first source/drain pattern 150 may be normal gate electrodes used as gates of the transistors. As another example, the gate electrode 120 disposed on one side of the first source/drain pattern 150 may be used as a gate of the transistor, but the gate electrode 120 disposed on the other side of the first source/drain pattern 150 may be a dummy gate electrode.

Although not shown, the gate electrodes 120 may be disposed on both sides of a second source/drain pattern 250 to be described below. The gate structures GS may be disposed on both sides of the second source/drain pattern 250 in the first direction DR1.

The gate insulating film 130 may extend along the upper surface of the field insulating film 105, the upper surface of the first lower pattern BP1, and the upper surface of the second lower pattern BP2. The gate insulating film 130 may enclose the first sheet pattern NS1. The gate insulating film 130 may enclose the second sheet pattern NS2. The gate insulating film 130 may be disposed along the periphery of the first sheet pattern NS1 and the periphery of the second sheet pattern NS2. The gate electrode 120 is disposed on the gate insulating film 130. The gate insulating film 130 may be disposed between the gate electrode 120 and the first sheet pattern NS1, and between the gate electrode 120 and the second sheet pattern NS2.

The gate insulating film 130 may include silicon oxide, silicon oxynitride, silicon nitride or a high dielectric constant material having a dielectric constant higher than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the gate insulating film 130 is shown as being a single film, this is only for convenience of explanation, and the embodiment is not limited thereto. The gate insulating film 130 may include a plurality of films. The gate insulating film 130 may include an interfacial film disposed between the first sheet pattern NS1 and the gate electrode 120, and between the second sheet pattern NS2 and the gate electrode 120, and a high dielectric constant insulating film.

The semiconductor device according to some embodiments may include an NC (Negative Capacitance) FET that uses a negative capacitor. For example, the gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide or lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) or tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al) or yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have paraelectric properties. The paraelectric material film may include at least one of, for example, a silicon oxide or a metal oxide having a high dielectric constant. The metal oxide included in the paraelectric material film may include, for example, but is not limited to, at least one of hafnium oxide, zirconium oxide, or aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film differs from a crystal structure of hafnium oxide included in the paraelectric material film.

The ferroelectric material film may have a thickness having the ferroelectric properties. The thickness of the ferroelectric material film may be, for example, but is not limited to, 0.5 to 10 nm. Since a critical thickness that exhibits the ferroelectric properties may vary for each ferroelectric material, the thickness of the ferroelectric material film may vary depending on the ferroelectric material.

As an example, the gate insulating film 130 may include one ferroelectric material film. As another example, the gate insulating film 130 may include a plurality of ferroelectric material films spaced apart from each other. The gate insulating film 130 may have a stacked film structure in which the plurality of ferroelectric material films and the plurality of paraelectric material films are alternately stacked.

The gate spacer 140 may be disposed on the side wall of the gate electrode 120. The gate spacer 140 may extend in the second direction DR2.

For example, the gate spacer 140 may not be disposed between the first sheet patterns NS1 adjacent to each other in the third direction DR3, and between the first sheet pattern NS1 and the first lower pattern BP1. The gate spacer 140 may include only an outer spacer.

The gate spacer 140 may include, for example, at least one of silicon nitride, silicon oxynitride, silicon oxide, silicon oxycarbonitride, silicon boronitride, silicon oxyboronitride, silicon oxycarbide or combinations thereof

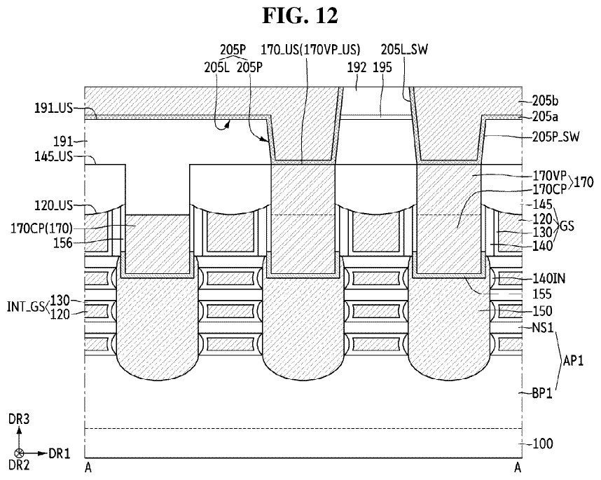

Although not shown, as an example, a cross-sectional view taken along the second active pattern AP2 in FIG. 1 may be similar to that of FIG. 2. As another example, a cross-sectional view taken along the second active pattern AP2 in FIG. 1 may be similar to that of FIG. 12, which will be described below.

The gate capping pattern 145 may be disposed on the upper surface 120_US of the gate electrode and the upper surface of the gate spacer 140. Unlike the shown example, the gate capping pattern 145 may be disposed between the gate spacers 140.

The gate capping pattern 145 may include, for example, at least one of silicon nitride, silicon oxynitride, silicon oxide, silicon carbonitride, silicon oxycarbonitride or combinations thereof. The gate capping pattern 145 may include a material having an etching selectivity with respect to a first interlayer insulating film 190.

The first source/drain pattern 150 is disposed on the substrate 100. The first source/drain pattern 150 may be disposed on the first lower pattern BP1. The first source/drain pattern 150 is in contact with the first sheet pattern NS1. For example, the first source/drain pattern 150 may be in contact with the gate insulating film 130 of the inner gate structure INT_GS.

The first source/drain pattern 150 may be disposed between the gate structures GS. The first source/drain pattern 150 may be disposed on at least one side of the gate structure GS. The first source/drain pattern 150 is disposed on a side surface of the gate electrode 120. For example, the first source/drain pattern 150 may be disposed on both sides of the gate structure GS. Unlike the shown example, the first source/drain pattern 150 is disposed on one side of the gate structure GS, but may not disposed on the other side of the gate structure GS.

The second source/drain pattern 250 is disposed on the substrate 100. The second source/drain pattern 250 may be disposed on the second lower pattern BP2. Although not shown, a shape in which the second source/drain pattern 250 is disposed on the second lower pattern BP2 may be similar to a shape in which the first source/drain pattern 150 is disposed in FIG. 2.

For example, the first source/drain pattern 150 may include a plurality of width expansion regions. In FIG. 2, the outer side wall of the first source/drain pattern 150 may have a wavy shape. A width of the first source/drain pattern 150 in the first direction DR1 in the width expansion region may increase or decrease as it goes away from the first lower pattern BP1. The width expansion region of the first source/drain pattern 150 may be defined between the first sheet patterns NS1 adjacent to each other in the third direction DR3. The width expansion region of the first source/drain pattern 150 may be defined between the first lower pattern BP1 and the first sheet pattern NS1. In the width expansion region of each first source/drain pattern 150, a point on which the first source/drain pattern 150 has the maximum width is located between the first sheet pattern NS1 and the first lower pattern BP1, or between the first sheet patterns NS1 adjacent in the third direction DR3.

The first source/drain pattern 150 may be included in the source/drain of a transistor which uses the first active pattern AP1, for example, the first sheet pattern NS1, as a channel region. The second source/drain pattern 250 may be included in the source/drain of a transistor which uses the second sheet pattern NS2 as a channel region.

Each of the first source/drain pattern 150 and the second source/drain pattern 250 may include an epitaxial pattern. The first source/drain pattern 150 and the second source/drain pattern 250 may include, for example, a semiconductor material.

The first source/drain pattern 150 and the second source/drain pattern 250 may include n-type impurities or p-type impurities. The n-type impurities may include at least one of phosphorus (P), arsenic (As), antimony (Sb) or bismuth (Bi). The p-type impurities may include, for example, at least one of boron (B) or gallium (Ga).

A source/drain etching stop film 156 may be disposed on the upper surface of the field insulating film 105, the side wall of the gate structure GS, the side wall of the first source/drain pattern 150, and the side wall of the second source/drain pattern 250.

The source/drain etching stop film 156 may include a material having an etching selectivity with respect to the first interlayer insulating film 190 to be described below. The source/drain etching stop film 156 may include, for example, silicon nitride, silicon oxynitride, silicon oxycarbonitride, silicon boronitride, silicon oxyboronitride, silicon carbonitride or combinations thereof. Unlike the shown example, the source/drain etching stop film 156 may not be formed.

The first interlayer insulating film 190 may be disposed on the field insulating film 105. The first interlayer insulating film 190 may be disposed on the side walls of the first source/drain pattern 150 and the side walls of the second source/drain pattern 250.

The first interlayer insulating film 190 may include, for example, at least one of silicon oxide, silicon nitride, silicon oxynitride or a low dielectric constant material. The low dielectric constant material may include, for example, but is not limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

The source/drain contact structure 170 may be disposed on the first active pattern AP1 and the second active pattern AP2. The source/drain contact structure 170 may be disposed on the first source/drain pattern 150. The source/drain contact structure 170 is connected to the first source/drain pattern 150 on the first active pattern AP1.

The source/drain contact structure 170 may extend in the third direction DR3 along the side wall of the gate electrode 120. On the basis of the lowermost part of the first source/drain pattern 150, the lowermost part of the source/drain contact structure 170 is lower than the upper surface 120_US of the gate electrode. A part of the source/drain contact structure 170 may enter the first source/drain pattern 150, but is not limited thereto.

The source/drain contact structure 170 may be disposed on the second source/drain pattern 250. The source/drain contact structure 170 is connected to the second source/drain pattern 250 on the second active pattern AP2.

Unlike the shown example, a part of the source/drain contact structure 170 connected to the first source/drain pattern 150 may be directly connected to the source/drain contact structure 170 connected to the second source/drain pattern 250. That is, in the semiconductor device according to some embodiments, at least one or more source/drain contact structures 170 may be disposed over the first active pattern AP1 and the second active pattern AP2.

The source/drain contact structure 170 may be disposed on the first interlayer insulating film 190. In the cross-sectional view such as FIG. 2, the source/drain contact structure 170 may penetrate the source/drain etching stop film 156.

The source/drain contact structure 170 may include a source/drain contact portion 170CP and a source/drain via portion 170VP. The source/drain contact portion 170CP is directly connected to the source/drain via portion 170VP.

The source/drain contact portion 170CP may extend in the second direction DR2. The source/drain contact portion 170CP may be a portion of the source/drain contact structure 170 that is connected to the first source/drain pattern 150 and the second source/drain pattern 250.

In the semiconductor device according to some embodiments, a width of the source/drain contact portion 170CP in the second direction DR2 may decrease as it goes away from the first source/drain pattern 150. For example, the source/drain contact portion 170CP may have a shape similar to a trapezoid.

The source/drain via portion 170VP may protrude from the source/drain contact portion 170CP in the third direction DR3. The source/drain via portion 170VP may be a portion of the source/drain contact structure 170 that is connected to the connection wiring 205.

The source/drain via portion 170VP may include an upper surface 170_US of the source/drain contact structure. The upper surface 170VP_US of the source/drain via portion may be the upper surface 170_US of the source/drain contact structure. The upper surface 170_US of the source/drain contact structure may be placed on the same plane as the upper surface 145_US of the gate capping pattern, but is not limited thereto.

In FIGS. 5 and 6, the source/drain via portion 170VP may include a first portion 170VP1 and a second portion 170VP2. The first portion 170VP1 of the source/drain via portion is disposed between the second portion 170VP2 of the source/drain via portion and the source/drain contact portion 170CP. The second portion 170VP2 of the source/drain via portion is disposed between the first portion 170VP1 of the source/drain via portion and the connection wiring 205. The second portion 170VP2 of the source/drain via portion may include an upper surface 170VP_US of the source/drain via portion. The second portion 170VP2 may be on the first portion 170VP1

A width of the first portion 170VP1 of the source/drain via portion in the second direction DR2 may decrease as it goes away from the first source/drain pattern 150.

In FIG. 5, the width of the second portion 170VP2 of the source/drain via portion in the second direction DR2 may increase, as it goes away from the first source/drain pattern 150. The width of the source/drain via portion 170VP in the second direction DR2 may decrease and then increase, as it goes away from the first source/drain pattern 150.

In FIG. 6, the width of the second portion 170VP2 of the source/drain via portion in the second direction DR2 may be constant, as it goes away from the first source/drain pattern 150. The width of the source/drain via portion 170VP in the second direction DR2 may decrease and then remain constant, as it goes away from the first source/drain pattern 150.

The source/drain via portion 170VP and the source/drain contact portion 170CP may be an integral structure. In the semiconductor device according to some embodiments, the source/drain contact structure 170 may have a single conductive film structure. For example, the source/drain contact structure 170 may be formed of one conductive material. In some cases, the source/drain contact structure 170 may include impurities that are unintentionally introduced in the process of forming the source/drain contact structure 170.

The source/drain contact structure 170 may include a metal. The source/drain contact structure 170 may include, but is not limited to, one of titanium (Ti), tungsten (W), molybdenum (Mo), ruthenium (Ru) or cobalt (Co). As an example, the source/drain contact structure 170 may include molybdenum (Mo).

A first contact silicide film 155 may be disposed between the source/drain contact structure 170 and the first source/drain pattern 150. A second contact silicide film 255 may be disposed between the source/drain contact structure 170 and the second source/drain pattern 250. Each of the first contact silicide film 155 and the second contact silicide film 255 may include, for example, a metal silicide material.

A second interlayer insulating film 191 may be disposed on the first interlayer insulating film 190 and the gate structure GS. For example, the second interlayer insulating film 191 may be disposed on the upper surface 145_US of the gate capping pattern.

The second interlayer insulating film 191 may be disposed on the source/drain contact structure 170. The second interlayer insulating film 191 may cover a side wall 170VP_SW of the source/drain via portion. For example, the second interlayer insulating film 191 may be in contact with the side wall 170VP_SW of the source/drain via portion.

The source/drain contact portion 170CP may include an upper surface that connects the side wall 170CP_SW of the source/drain contact portion and the side wall 170VP_SW of the source/drain via portion. The second interlayer insulating film 191 may cover the upper surface of the source/drain contact portion 170CP. For example, the second interlayer insulating film 191 may be in contact with the upper surface of the source/drain contact portion 170CP.

In the semiconductor device according to some embodiments, the second interlayer insulating film 191 may cover the side wall 170CP_SW of the source/drain contact portion. For example, the second interlayer insulating film 191 may be in contact with the side wall 170CP_SW of the source/drain contact portion.

Since the second interlayer insulating film 191 is disposed on the gate structure GS, the upper surface 191_US of the second interlayer insulating film may be higher than the upper surface 145_US of the gate capping pattern on the basis of the upper surface of the first sliding pattern AP1.

In FIG. 4, the upper surface 191_US of the second interlayer insulating film may be higher than the upper surface 170VP_US of the source/drain via portion on the basis of the boundary between the source/drain contact structure 170 and the first contact silicide film 155. That is, the upper surface 191_US of the second interlayer insulating film may be higher than the upper surface 170_US of the source/drain contact structure. A height H12 from the bottom surface of the source/drain contact structure 170 to the upper surface 191_US of the second interlayer insulating film may be larger than a height H11 from the bottom surface of the source/drain contact structure 170 to the upper surface 170VP_US of the source/drain via portion. The bottom surface of the source/drain contact structure 170 may be a surface in the source/drain contact portion 170CP that is connected to the first source/drain pattern 150.

The second interlayer insulating film 191 may include, for example, at least one of silicon oxide, silicon nitride, silicon oxynitride or a low dielectric constant material. In the semiconductor device according to some embodiments, the second interlayer insulating film 191 may include silicon nitride.

The gate contact 175 may be disposed inside the gate structure GS and the second interlayer insulating film 191. The gate contact 175 may be disposed on the gate electrode 120 and may be extend through the second interlayer insulating film 191 to contact the gate electrode 120. The gate contact 175 may penetrate the gate capping pattern 145, and may be connected to the gate electrode 120.

The gate contact 175 may be disposed at a position that overlaps the gate structure GS. Although the gate contact 175 is shown as being disposed at a position that does not overlap the first active pattern AP1 and the second active pattern AP2 in FIG. 1, the embodiment is not limited thereto. Unlike the shown example, the gate contact 175 may be disposed at a position that overlaps at least one of the first active pattern AP1 and the second active pattern AP2.

The upper surface 175_US of the gate contact may be higher than the upper surface 170_US of the source/drain contact structure on the basis of the bottom surface of the field insulating film 105. The upper surface 175_US of the gate contact may be placed on the same plane as the upper surface 191_US of the second interlayer insulating film, but the embodiment is not limited thereto.

The gate contact 175 may include a gate contact barrier film 175a and a gate contact filling film 175b. The gate contact barrier film 175a may be disposed between the gate electrode 120 and the gate contact filling film 175b. For example, the gate contact 175 may have a multi-material film structure including different materials from each other.

The gate contact barrier film 175a may include, for example, but is not limited to, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh) or a two-dimensional (2D) material. The gate contact filling film 175b may include, for example, but is not limited to, aluminum (Al), tungsten (W), cobalt (Co), copper (Cu), ruthenium (Ru), silver (Ag), gold (Au), manganese (Mn) or molybdenum (Mo).

A third interlayer insulating film 192 may be disposed on the second interlayer insulating film 191, the source/drain contact structure 170, and the gate contact 175. The third interlayer insulating film 192 may include, for example, at least one of a silicon oxide, a silicon nitride, a silicon oxynitride or a low dielectric constant material.

An etching stop film 195 may be disposed on the second interlayer insulating film 191. The etching stop film 195 may extend along the upper surface 191_US of the second interlayer insulating film 191. The etching stop film 195 may be disposed between the second interlayer insulating film 191 and the third interlayer insulating film 192.

The etching stop film 195 may include a material having an etch selectivity with respect to the third interlayer insulating film 192. The etching stop film 195 may include, for example, one of aluminum oxide, aluminum nitride or aluminum oxycarbide. The etching stop film 195 is shown as being a single film, but the embodiment is not limited thereto.

The connection wiring 205 may be disposed on the source/drain contact structure 170 and the gate contact 175. The connection wiring 205 may be disposed inside the second interlayer insulating film 191, the etching stop film 195, and the third interlayer insulating film 192.

The connection wiring 205 passes through the etching stop film 195, and may be connected to the source/drain contact structure 170 and the gate contact 175. The connection wiring 205 may be in contact with the source/drain contact structure 170 and the gate contact 175. The connection wiring 205 may be in contact with the upper surface 170VP_US of the source/drain via portion. The connection wiring 205 may be in contact with the upper surface 175_US of the gate contact.

The connection wiring 205 may include a line portion 205L and a protruding portion 205P. A protruding portion 205P of the connection wiring may be disposed between the line portion 205L of the connection wiring and the source/drain contact structure 170.

A part of the connection wirings 205 may include the protruding portion 205P of the connection wiring and the line portion 205L of the connection wiring. The remainder of the connection wirings 205 may include the line portion 205L of the connection wiring without the protruding portion 205P of the connection wiring.

The line portion 205L of the connection wiring may be disposed on the second interlayer insulating film 191. For example, the line portion 205L of the connection wiring may be disposed inside the third interlayer insulating film 192 and the etching stop film 195. The third interlayer insulating film 192 and the etching stop film 195 may cover the side wall 205L_SW of the line portion of the connection wiring. The line portion 205L of the connection wiring may extend, for example, in the first direction DR1.

The gate contact 175 may be connected to the line portion 205L of the connection wiring. The line portion 205L of the connection wiring may be in contact with the upper surface 175_US of the gate contact.

The protruding portion 205P of the connection wiring may protrude from the line portion 205L of the connection wiring in the third direction DR3. The protruding portion 205P of the connection wiring may protrude from the line portion 205L of the connection wiring toward the source/drain contact structure 170.

The protruding portion 205P of the connection wiring may be disposed inside the second interlayer insulating film 191. The protruding portion 205P of the connection wiring may be connected to the source/drain contact structure 170. The protruding portion 205P of the connection wiring may be in contact with the upper surface 170_US of the source/drain contact structure. The second interlayer insulating film 191 may cover the side wall 205P_SW of the protruding portion of the connection wiring.

The protruding portion 205P of the connection wiring and the line portion 205L of the connection wiring may be divided on the basis of the upper surface 191_US of the second interlayer insulating film.

The etching stop film 195 may not extend along the boundary between the protruding portion 205P of the connection wiring and the second interlayer insulating film 191. The etching stop film 195 is not disposed on the side wall 205P_SW of the protruding portion of the connection wiring. The etching stop film 195 does not extend along the side wall 205P_SW of the protruding portion of the connection wiring. In the semiconductor device according to some embodiments, the second interlayer insulating film 191 may be in contact with the side wall 205P_SW of the protruding portion of the connection wiring.

The connection wiring 205 may include, for example, a wiring barrier film 205a and a wiring filling film 205b. The protruding portion 205P of the connection wiring and the line portion 205L of the connection wiring may include a wiring barrier film 205a and a wiring filling film 205b.

The wiring barrier film 205a may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh) or a two-dimensional (2D) material. The wiring filling film 205b may include, for example, at least one of aluminum (Al), copper (Cu), tungsten (W), cobalt (Co), ruthenium (Ru), silver (Ag), gold (Au), manganese (Mn) or molybdenum (Mo).

The 2D material may include a 2D allotrope or a 2D compound, and may include, but is not limited to, at least one of graphene, boron nitride (BN), molybdenum sulfide, molybdenum selenide, tungsten sulfide, tungsten selenide, and tantalum sulfide. That is, since the above-mentioned 2D materials are only listed by way of example, the 2D materials that may be included in the semiconductor device of the present disclosure are not limited by the above-mentioned materials.

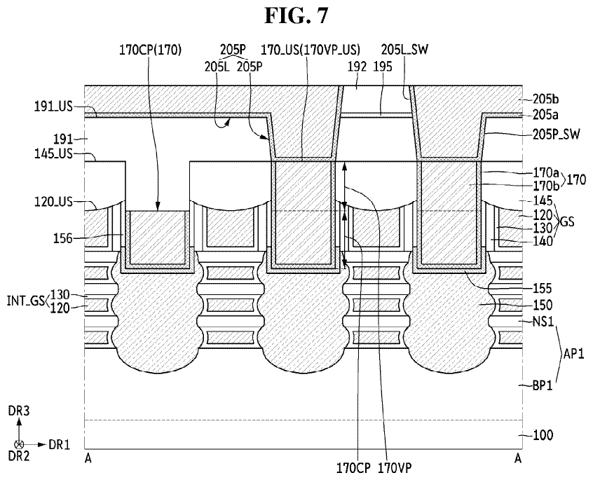

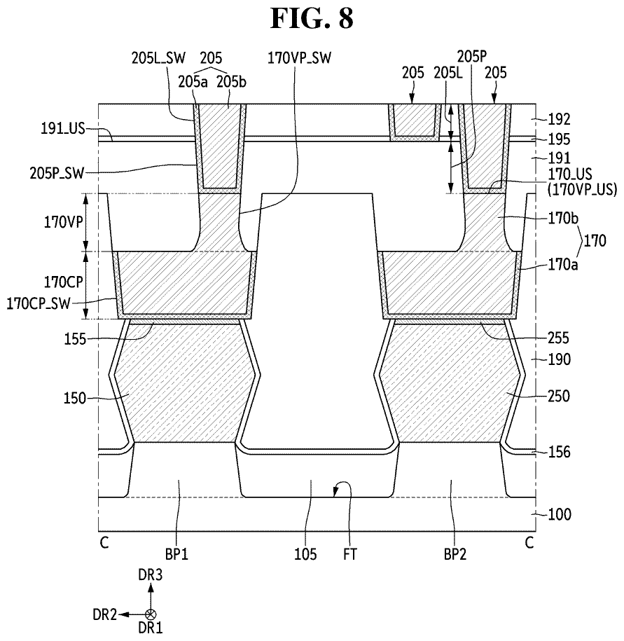

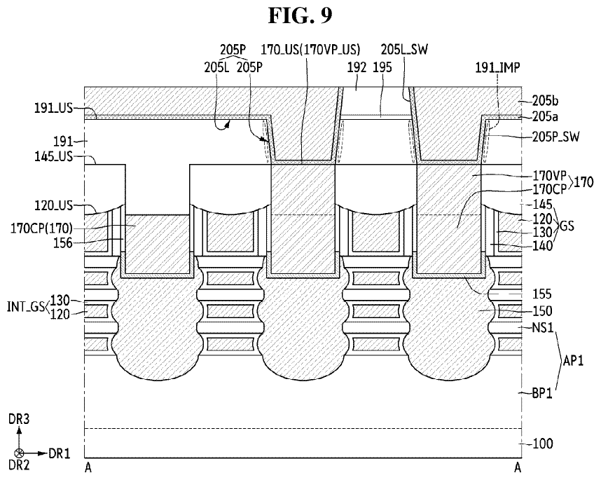

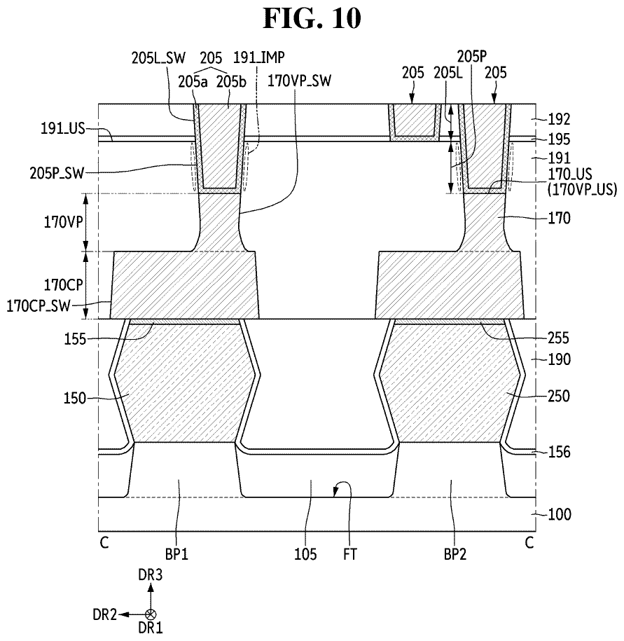

FIGS. 7 and 8 are diagrams for explaining a semiconductor device according to some embodiments. FIGS. 9 and 10 are diagrams for explaining a semiconductor device according to some embodiments. For convenience of explanation, differences from those explained using FIGS. 1 to 6 will be mainly explained.

Referring to FIGS. 7 and 8, in the semiconductor device according to some embodiments, the source/drain contact structure 170 may include a contact barrier film 170a and a contact filling film 170b.

The contact barrier film 170a may be disposed between the contact filling film 170b and the first source/drain pattern 150. The contact barrier film 170a is disposed between the contact filling film 170b and the second source/drain pattern 250.

For example, the width of the source/drain contact portion 170CP in the second direction DR2 may increase as it goes away from the first source/drain pattern 150. For example, the source/drain contact portion 170CP may have a shape similar to an inverted trapezoid.

The upper surface of the first interlayer insulating film 190 may be placed in the same plane as the upper surface 145_US of the gate capping pattern. The upper surface of the first interlayer insulating film 190 may be placed in the same plane as the upper surface 170_US of the source/drain contact structure.

The first interlayer insulating film 190 may cover the side wall 170CP_SW of the source/drain contact portion. For example, the first interlayer insulating film 190 may be in contact with the side wall 170CP_SW of the source/drain contact portion.

The source/drain via portion 170VP and the source/drain contact portion 170CP may include a contact barrier film 170a and a contact filling film 170b. In a cross-sectional view such as FIG. 8, the contact filling film 170b included in the source/drain via portion 170VP and the source/drain contact portion 170CP may be an integral structure.

The contact barrier film 170a may include, but is not limited to, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh) or a two-dimensional (2D) material.

The contact filling film 170b may include, for example, but is not limited to aluminum (Al), tungsten (W), cobalt (Co), copper (Cu), ruthenium (Ru), silver (Ag), gold (Au), manganese (Mn) or molybdenum (Mo).

Referring to FIGS. 9 and 10, in the semiconductor device according to some embodiments, the second interlayer insulating film 191 may further include an impurity accumulation region 191_IMP disposed along the side wall 205P_SW of the protruding portion of the connection wiring.

The impurity accumulation region 191_IMP may be disposed on the side wall 205P_SW of the protruding portion of the connection wiring. The impurity accumulation region 191_IMP may be disposed along the boundary between the protruding portion 205P of the connection wiring and the second interlayer insulating film 191.

The impurity accumulation region 191_IMP may not be disposed along the boundary between the second interlayer insulating film 191 and the source/drain via portion 170VP. The impurity accumulation region 191_IMP may be located above the upper surface 170_US of the source/drain contact structure.

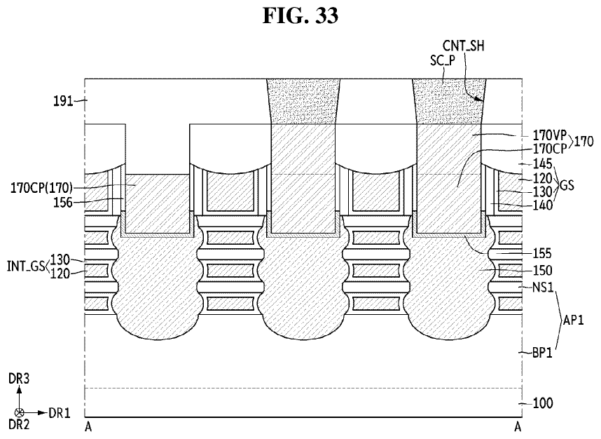

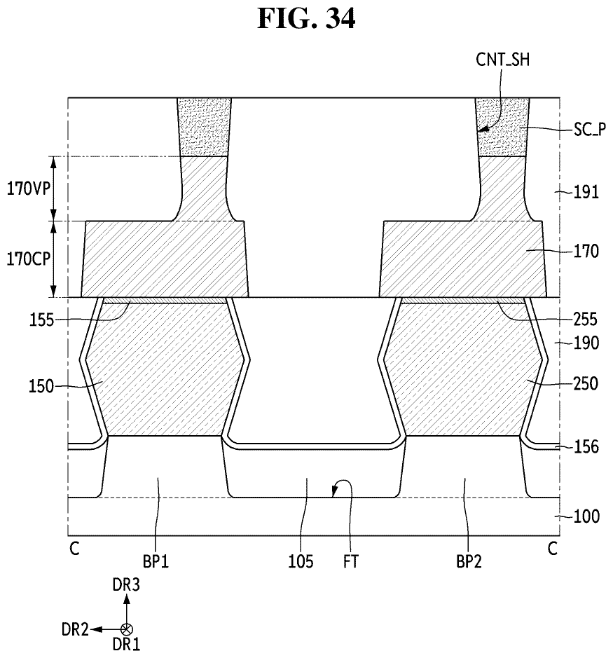

The impurity accumulation region 191_IMP may include, but is not limited to, one of carbon (C) or titanium (Ti). For example, the impurity element included in the impurity accumulation region 191_IMP may vary depending on the material included in the sacrificial pattern (SC_P of FIGS. 33 and 34).

Although the impurity accumulation region 191_IMP is shown to be present in the form in which the impurity element is doped inside the second interlayer insulating film 191, the embodiment is not limited thereto. The impurity accumulation region 191_IMP may be present in the form of a thin film on the surface of the second interlayer insulating film 191 that faces the protruding portion 205P of the connection wiring.

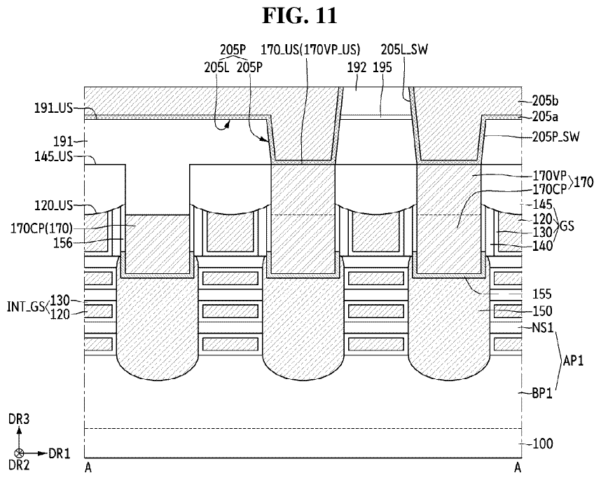

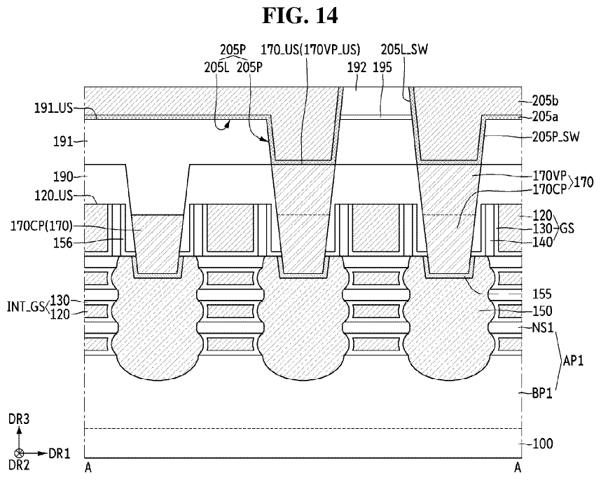

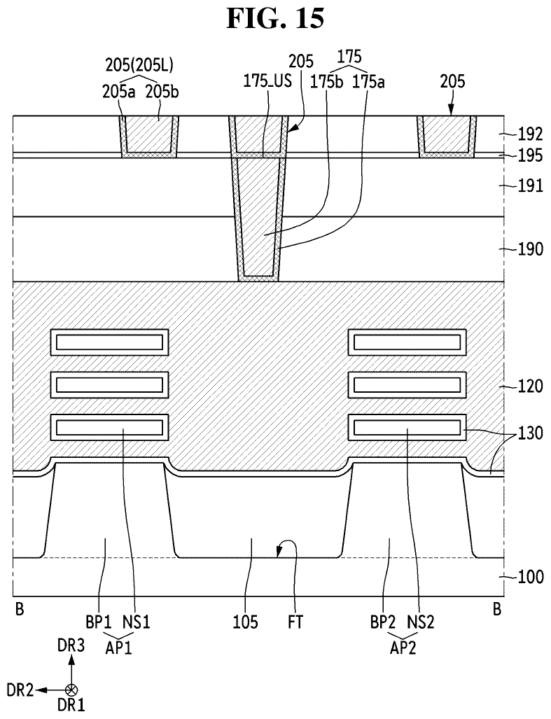

FIGS. 11 to 13 are diagrams for explaining a semiconductor device according to some embodiments. FIGS. 14 and 15 are diagrams for explaining a semiconductor device according to some embodiments. For convenience of explanation, differences from those explained using FIGS. 1 to 6 will be mainly explained.

Referring to FIG. 11, in the semiconductor device according to some embodiments, the first source/drain pattern 150 does not include a width expansion region.

A width of the first source/drain pattern 150 in the first direction DR1 may increase and then decrease, as it goes away from the first lower pattern BP1.

Referring to FIG. 12, the semiconductor device according to some embodiments may further include a plurality of inner spacers 140IN disposed between the first sheet patterns NS1 adjacent in the third direction DR3.

The inner spacer 140IN may be disposed between the inner gate structure INT_GS and the first source/drain pattern 150. Because the inner spacer 140IN may be disposed, the inner gate structure INT_GS may not be in contact with the first source/drain pattern 150.

The inner spacer 140IN may include, for example, silicon nitride, silicon oxynitride, silicon oxide, silicon oxycarbonitride, silicon boronitride, silicon oxyboronitride, silicon oxycarbide or a combination thereof

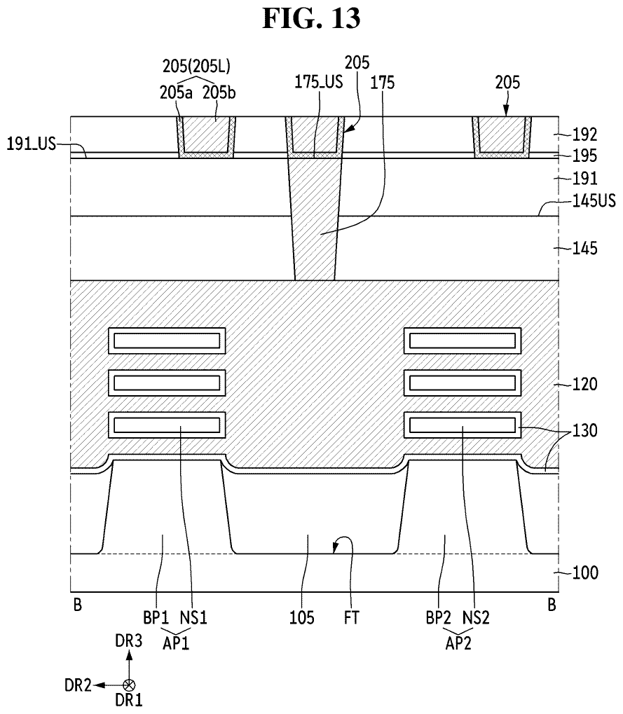

Referring to FIG. 13, the gate contact 175 may have a single conductive film structure.

The gate contact 175 may include a metal. The gate contact 175 may include, but is not limited to, one of titanium (Ti), molybdenum (Mo), ruthenium (Ru) or cobalt (Co).

Referring to FIGS. 14 and 15, in the semiconductor device according to some embodiments, the gate structure GS may include a gate electrode 120, a gate insulating film 130, and a gate spacer 140.

The gate structure GS may not include a gate capping pattern (145 of FIG. 2). The upper surface of the gate structure GS may include the upper surface 120_US of the gate electrode.

The first interlayer insulating film 190 may be disposed on the upper surface 120_US of the gate electrode. The first interlayer insulating film 190 may cover the upper surface 120_US of the gate electrode.

A part of the source/drain contact structure 170 may protrude beyond the upper surface of the gate structure GS in the third direction DR3. The upper surface 170_US of the source/drain contact structure may be higher than the upper surface of the gate structure GS.

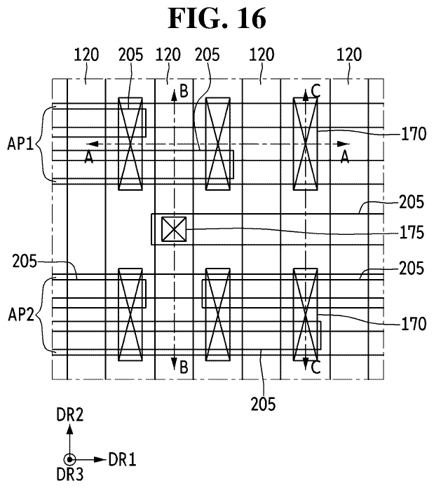

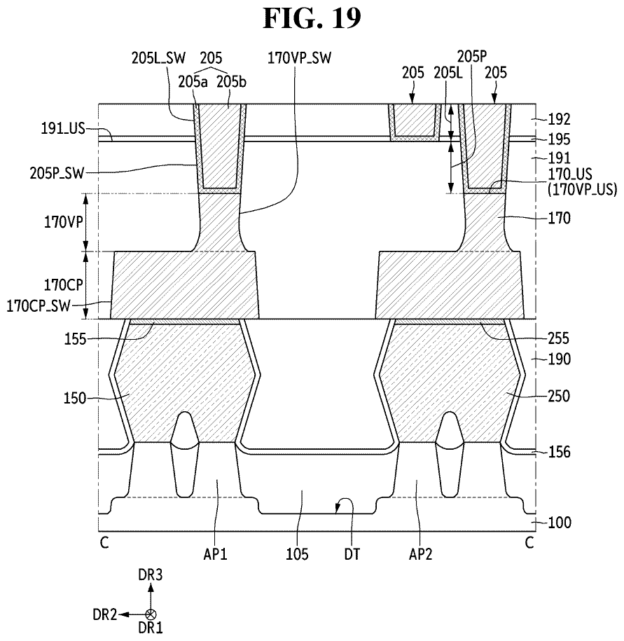

FIGS. 16 to 19 are diagrams for explaining a semiconductor device according to some embodiments. For convenience of explanation, differences from those explained using FIGS. 1 to 6 will be mainly explained.

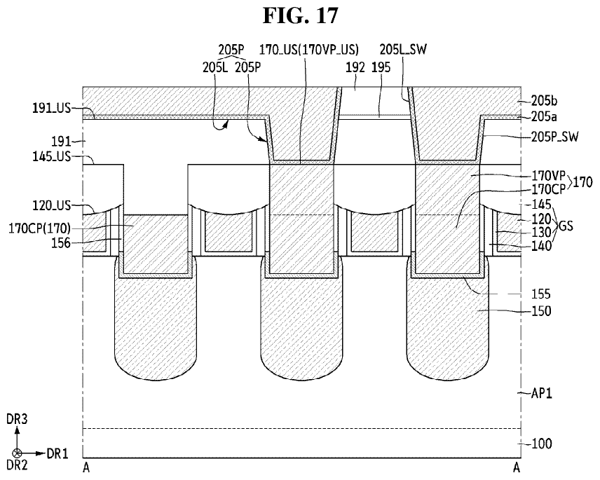

For reference, FIG. 16 is an example layout diagram for explaining a semiconductor device according to some embodiments. FIGS. 17 to 19 are cross-sectional views taken along A-A, B-B, and C-C of FIG. 16.

Referring to FIGS. 16 to 19, in the semiconductor device according to some embodiments, each of the first active pattern AP1 and the second active pattern AP2 may be fin-shaped patterns that protrude above an upper surface of the field insulating film 105.

Each of the first active pattern AP1 and the second active pattern AP2 may be disposed in an active region defined by a deep trench DT. The deep trench DT may define a field region disposed between the active regions.

Although each of two first active patterns AP1 and two second active patterns AP2 is shown to be disposed in the active region, the embodiment is not limited thereto. The number of first active patterns AP1 and second active patterns AP2 disposed in the active region may be one or may be three or more. Each of the first active pattern AP1 disposed in the active region and the second active pattern AP2 disposed in the active region may be separated by a fin trench FT extending long in the first direction DR1.

The field insulating film 105 may fill the deep trench DT.

Each of the first active pattern AP1 and the second active pattern AP2 may include, for example, silicon or germanium, which is an elemental semiconductor material. The first active pattern AP1 and the second active pattern AP2 may include a compound semiconductor, and may include, for example, a group IV-IV compound semiconductor or a group III-V compound semiconductor. As an example, the first active pattern AP1 and the second active pattern AP2 may include the same material. For example, the first active pattern AP1 and the second active pattern AP2 may be, but are not limited to, silicon fin-shaped patterns including silicon.

As another example, the first active pattern AP1 may include a material different from the second active pattern AP2. When the first active pattern AP1 is disposed in a PMOS formation region and the second active pattern AP2 is disposed in an NMOS formation region, the first active pattern AP1 may be, but is not limited to, a fin-shaped pattern including silicon-germanium, and the second active pattern AP2 may be, but is not limited to, a fin-shaped pattern including silicon.

The gate structure GS does not include an inner gate structure (INT_GS of FIG. 2).

The first source/drain patterns 150 may be connected to the respective first active patterns AP1. The second source/drain patterns 250 may be connected to the respective second active patterns AP2.

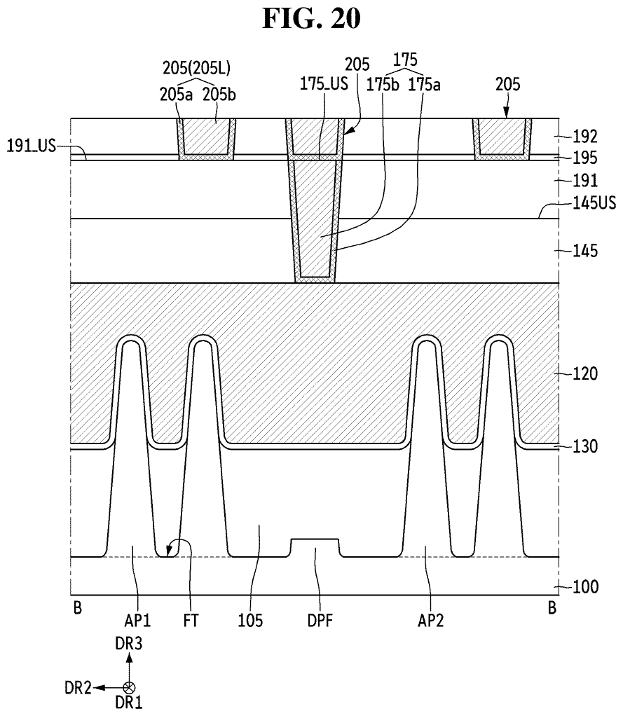

FIG. 20 is a diagram for explaining a semiconductor device according to some embodiments. For convenience of explanation, differences from those explained using FIGS. 16 to 19 will be mainly explained.

Referring to FIG. 20, the semiconductor device according to some embodiments may further include a dummy protruding pattern DPF disposed in a field region that divides the active regions.

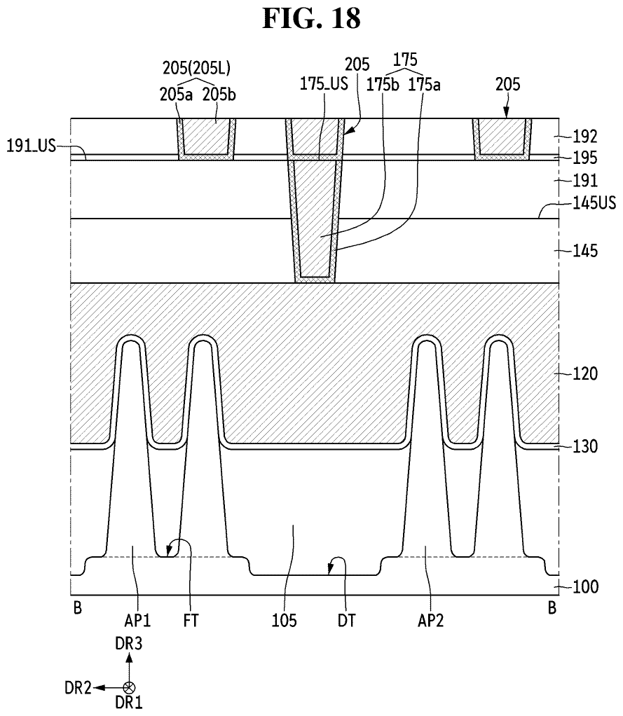

A deep trench (DT of FIG. 18) is not formed in the field region. The field insulating film 105 covers the upper side of the dummy protruding pattern DPF. The dummy protruding pattern DPF includes a semiconductor material.

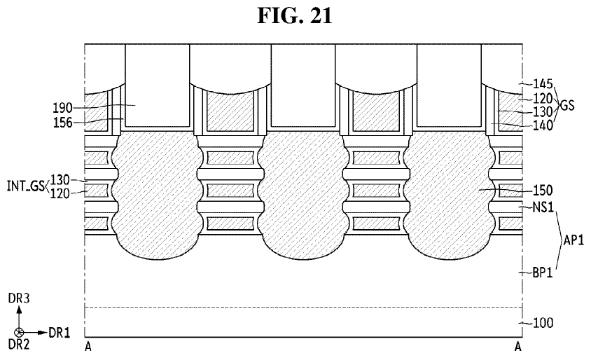

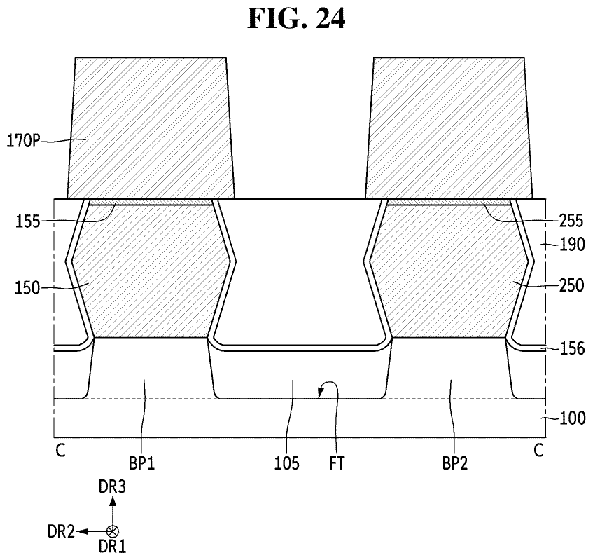

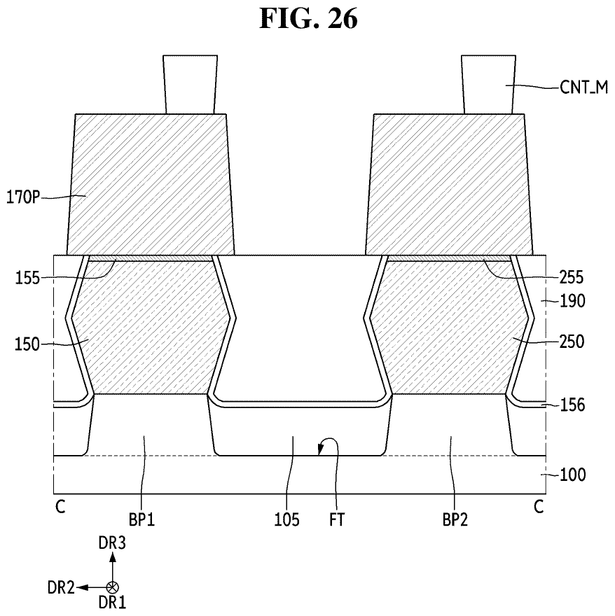

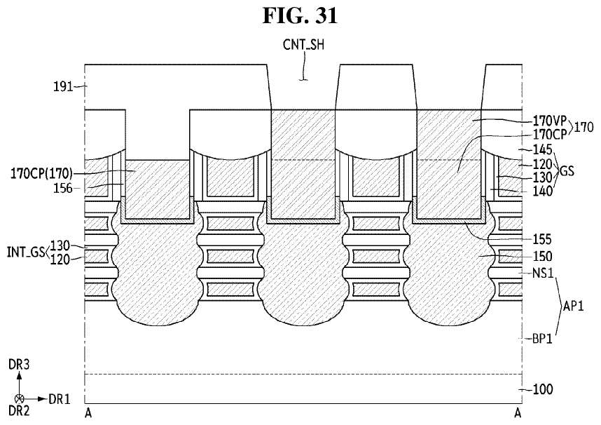

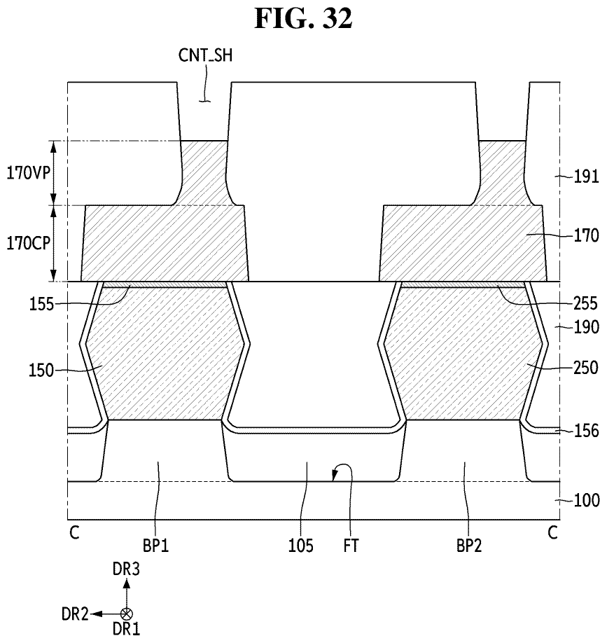

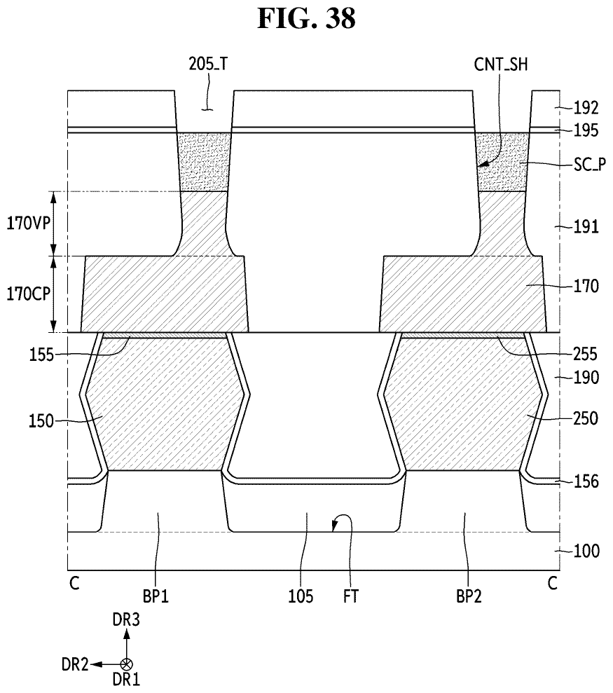

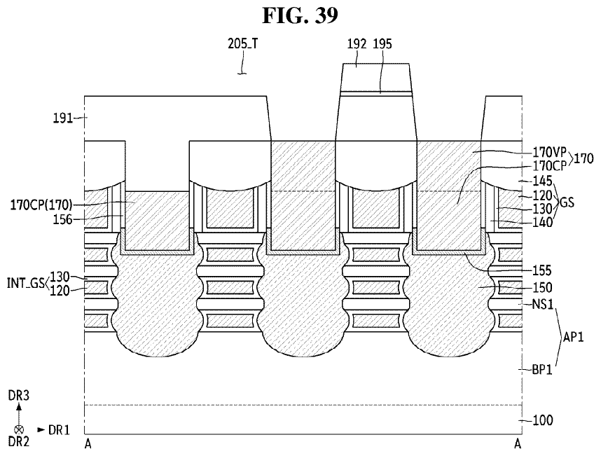

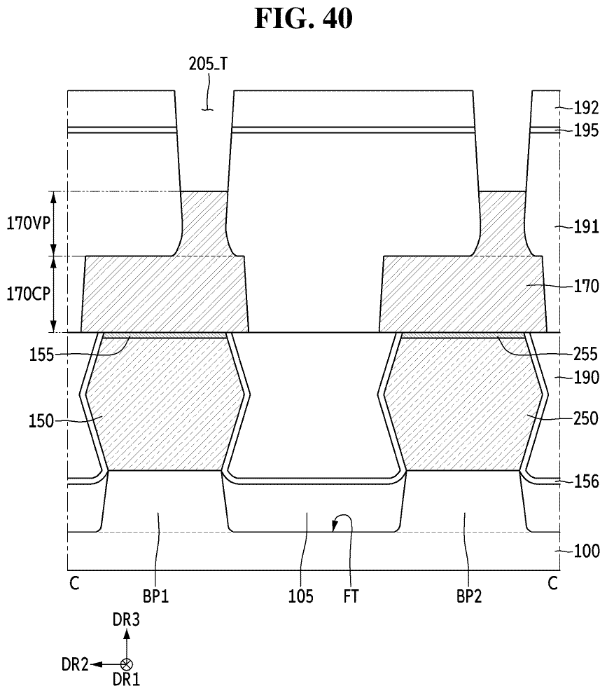

FIGS. 21 to 40 are intermediate stage diagrams for explaining a method for fabricating a semiconductor device according to some embodiments.

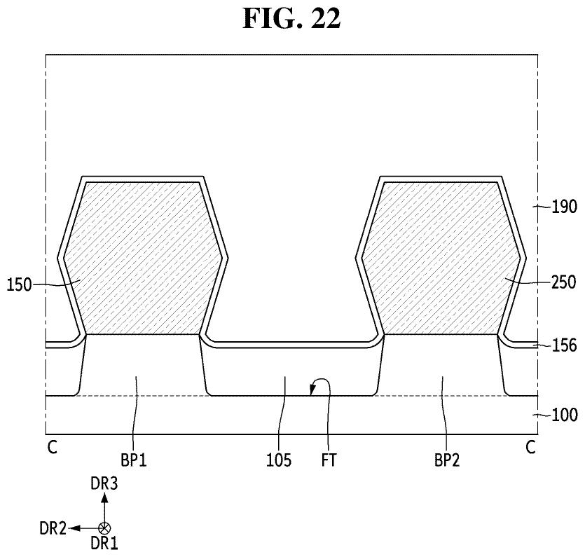

Referring to FIGS. 21 and 22, a first source/drain pattern 150 may be formed on the first active pattern AP1.

A second source/drain pattern 250 may be formed on the second active pattern AP2.

A source/drain etching stop film 156 and a first interlayer insulating film 190 may be sequentially formed on the first source/drain pattern 150 and the second source/drain pattern 250.

After forming the first interlayer insulating film 190, a gate structure GS may be formed through a replacement metal gate (RMG) process. During the formation of the gate capping pattern 145, a part of the source/drain etching stop film 156 may be etched. As a result, the gate capping pattern 145 may be formed on the source/drain etching stop film 156, but is not limited thereto.

Referring to FIGS. 21 to 24, a pre-source/drain contact 170P may be formed on the first source/drain pattern 150 and the second source/drain pattern 250.

More specifically, after forming the gate structure GS, by removing a part of the first interlayer insulating film 190, a source/drain contact trench may be formed between the adjacent gate structures GS. The source/drain contact trench may extend in the second direction DR2. The source/drain contact trench may expose the first source/drain pattern 150 and the second source/drain pattern 250.

Next, a source/drain contact film may be formed inside the source/drain contact trench. The source/drain contact film may fill the source/drain contact trench. The source/drain contact film may have a linear shape extending in the second direction DR2.

Thereafter, the source/drain contact layer may be patterned to form a pre-source/drain contact 170P. The pre-source/drain contact 170P may have a single conductive film structure.

Unlike the shown example, a contact barrier film 170a and a contact filling film 170b may be formed inside the source/drain contact trench, as shown in FIGS. 7 and 8.

As an example, the first contact silicide film 155 and the second contact silicide film 255 may be formed before the source/drain contact film is formed. As another example, the first contact silicide film 155 and the second contact silicide film 255 may be formed during the formation of the source/drain contact film.

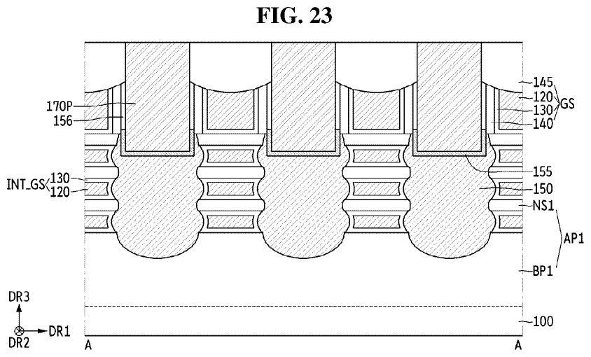

Referring to FIGS. 23 to 26, a contact mask pattern CNT_M may be formed on the pre-source/drain contact 170P.

More specifically, a sacrificial interlayer insulating film may be formed on the first interlayer insulating film 190. The sacrificial interlayer insulating film may be formed between the pre-source/drain contacts 170P adjacent to each other in the second direction DR2.

Next, a contact mask pattern CNT_M may be formed on the pre-source/drain contact 170P and the sacrificial interlayer insulating film. The contact mask pattern CNT_M may be formed at a position that overlaps the first source/drain contact 170P in the third direction DR3. The contact mask pattern CNT_M may include, but is not limited to, silicon oxide.

The sacrificial interlayer insulating film may then be removed.

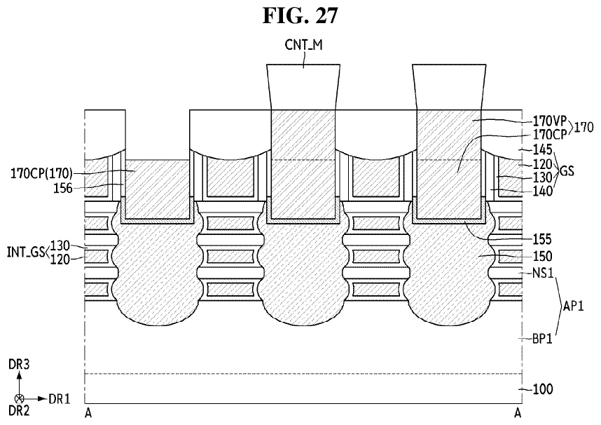

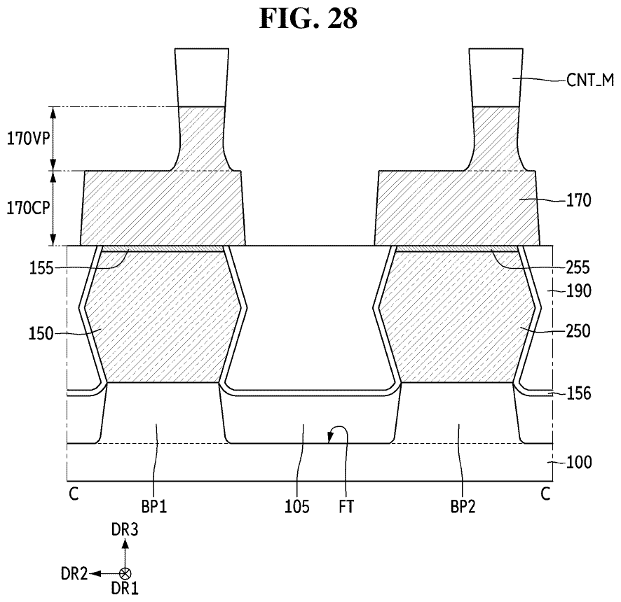

Unlike the shown example, the sacrificial interlayer insulating film may be removed after the source/drain contact structure (170 of FIGS. 27 and 28) is formed.

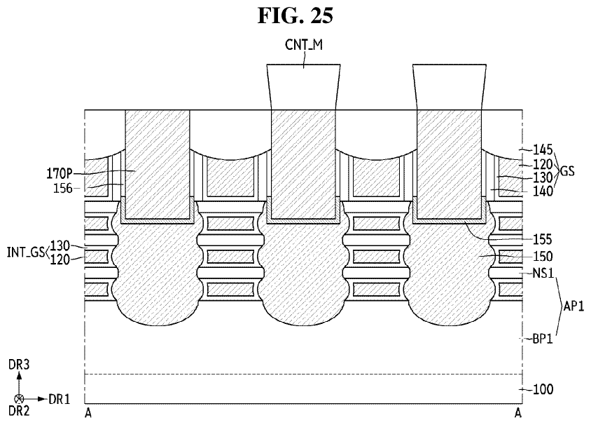

Referring to FIGS. 25 to 28, a part of the first source/drain contact 170P may be removed, using the contact mask pattern CNT_M as an etching mask.

A part of the first source/drain contact 170P may be removed to form the source/drain contact structure 170 on the first source/drain pattern 150 and the second source/drain pattern 250. The part of the first source/drain contact 170P may be removed to form the source/drain via portion 170VP.

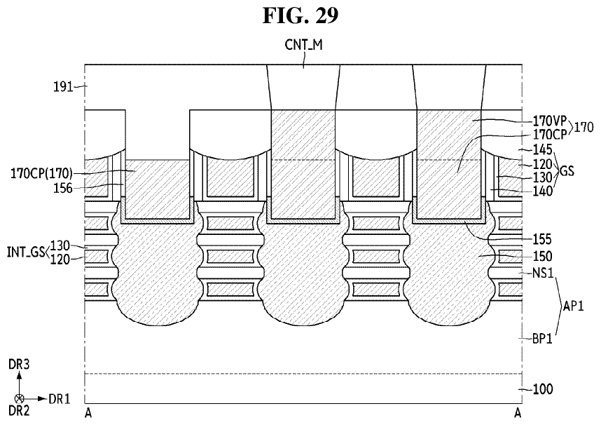

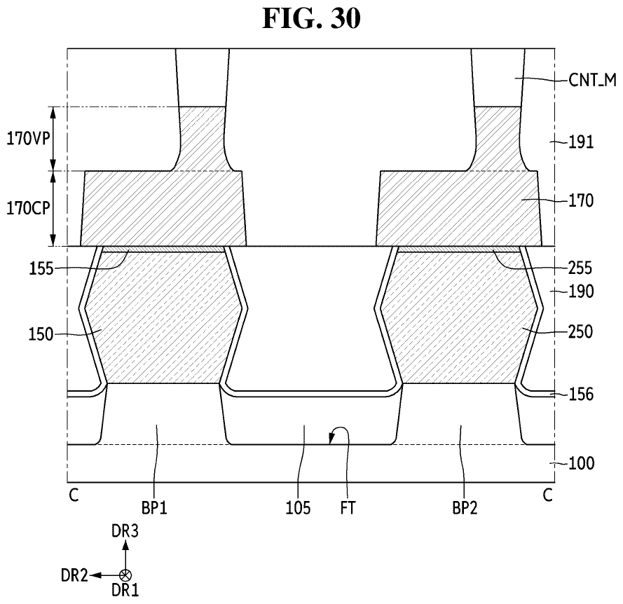

Referring to FIGS. 29 and 30, a second interlayer insulating film 191 may be formed on the source/drain contact structure 170.

The second interlayer insulating film 191 may cover side walls of the contact mask pattern CNT_M. The second interlayer insulating film 191 does not cover the upper surface of the contact mask pattern CNT_M. The second interlayer insulating film 191 may include an insulating material having an etching selectivity with respect to the contact mask pattern CNT_M.

Referring to FIGS. 29 to 32, the contact mask pattern CNT_M may be removed to form a sacrificial contact hole CNT_SH inside the second interlayer insulating film 191.

The sacrificial contact hole CNT_SH may expose the source/drain contact structure 170. The sacrificial contact hole CNT_SH may expose the upper surface of the source/drain via portion 170VP.

Referring to FIGS. 33 and 34, a sacrificial pattern SC_P may be formed inside the sacrificial contact hole CNT_SH.

The sacrificial pattern SC_P may fill the sacrificial contact hole CNT_SH. The sacrificial pattern SC_P may be formed inside the second interlayer insulating film 191. The sacrificial pattern SC_P may be formed on the upper surface of the source/drain via portion 170VP.

As an example, the sacrificial pattern SC_P may include SOH (Spin On Hardmask). The sacrificial pattern SC_P includes carbon. As another example, the sacrificial pattern SC_P may include titanium oxide. For example, the titanium oxide may be, but is not limited to, titanium dioxide.

The material included in the sacrificial pattern SC_P is not limited to the above-mentioned materials. The sacrificial pattern SC_P may include a material having a high etching selectivity with respect to the second interlayer insulating film 191 and the source/drain contact structure 170.

Since the sacrificial pattern SC_P is formed in the sacrificial contact hole CNT_SH, an impurity accumulation region (191_IMP of FIGS. 9 and 10) may be formed in some cases.

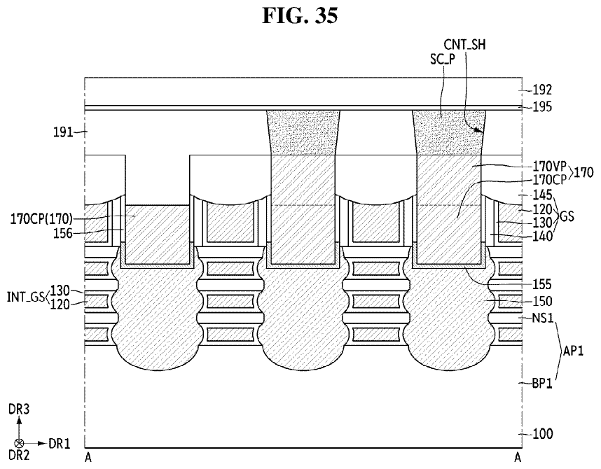

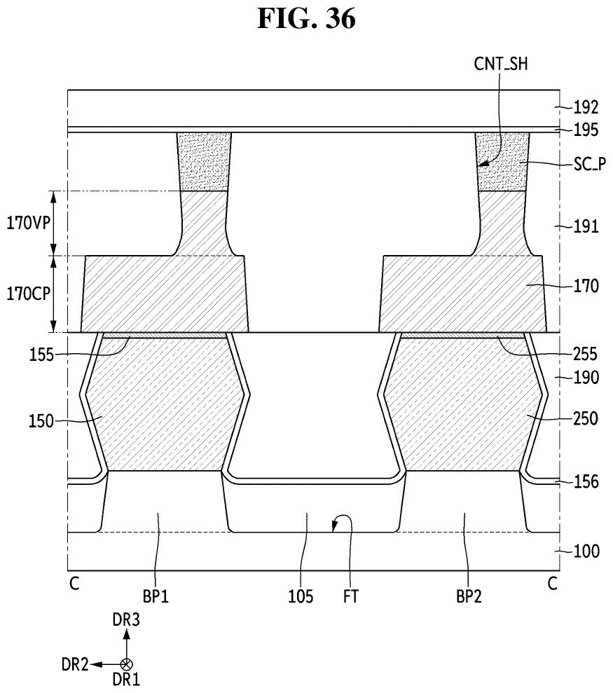

Referring to FIGS. 35 and 36, an etching stop film 195 and a third interlayer insulating film 192 may be sequentially formed on the second interlayer insulating film 191 and the sacrificial pattern SC_P.

The etching stop film 195 may be formed along the upper surface of the second interlayer insulating film 191 and the upper surface of the sacrificial pattern SC_P. The etching stop film 195 covers the upper surface of the second interlayer insulating film 191 and the upper surface of the sacrificial pattern SC_P.

Referring to FIGS. 35 to 38, a connection wiring trench 205_T may be formed in the etching stop film 195 and the third interlayer insulating film 192.

The connection wiring trench 205_T may expose the sacrificial pattern SC_P.

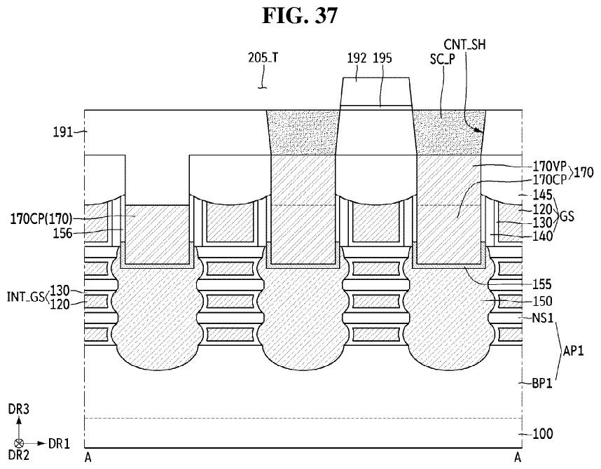

Referring to FIGS. 37 to 40, the sacrificial pattern SC_P exposed by the connection wiring trench 205_T may be removed.

The sacrificial pattern SC_P may be removed to expose the source/drain contact structure 170. The connection wiring trench 205_T may expose an upper surface of the source/drain contact structure 170. A part of the connection wiring trench 205_T is formed inside the second interlayer insulating film 191.

Next, referring to FIGS. 2 and 4, the connection wiring 205 may be formed inside the connection wiring trench 205_T. The connection wiring 205 may fill the connection wiring trench 205_T. The connection wiring 205 is connected to the source/drain contact structure 170 exposed by the connection wiring trench 205_T.

In an embodiment, a method of manufacturing a semiconductor device may include forming a sacrificial contact hole in a first interlayer insulating film on a substrate, the first interlayer insulating film covering a first source/drain contact structure connected to a first source/drain pattern, a second source/drain contact structure connected to a second source/drain pattern, and a stack of sheets patterns and a gate structure between the first source/drain pattern and the second source/drain pattern, the sacrificial contact hole exposing an upper surface of the first source/drain contact structure and an upper surface of the second source/drain contact structure, and the first source/drain contact structure and second source/drain contact structure each including a source/drain contact portion and a source/drain via portion protruding from the source/drain contact portion in a second direction; forming a sacrificial pattern that fills the sacrificial contact hole; sequentially forming an etching stop film along an upper surface of the first interlayer insulating film and a second interlayer insulating film on the etching stop film; forming a connection wiring trench in the etching stop film and the second interlayer insulating film to expose sacrificial pattern; removing the sacrificial pattern; and forming a connection wiring in the connection wiring trench and the sacrificial contact hole, wherein the connection wiring may contact an upper surface of the source/drain via portion of the first source/drain contact structure and the connection wiring may contact an upper surface of the source/drain via portion of the second source/drain contact structure.

The first interlayer insulating film may cover a sidewall of the source/drain via portion of the first source/drain contact structure and the first interlayer insulating film may cover a sidewall of the source/drain via portion of the second source/drain contact structure.

The first interlayer insulating film may include at least one of silicon oxide, silicon nitride, silicon oxynitride, or a low dielectric constant material.

The etching stop film may include one of aluminum oxide, aluminum nitride, or aluminum oxycarbide, and the second interlayer insulating film may include at least one of silicon oxide, silicon nitride, silicon oxynitride, or a low dielectric constant material.

The sacrificial pattern may include spin on hardmask, carbon, or titanium oxide.

In concluding the detailed description, those skilled in the art will appreciate that many variations and modifications may be made to the presented embodiments without substantially departing from the principles of the present disclosure. Therefore, the disclosed presented embodiments of the disclosure are used in a generic and descriptive sense only and not for purposes of limitation.

What is claimed is:

1. A semiconductor device comprising:
a source/drain pattern on a substrate;
a source/drain contact structure connected to the source/drain pattern,
the source/drain contact structure including a source/drain contact portion and a source/drain via portion,
the source/drain contact portion extending in a first direction, and
the source/drain via portion protruding from the source/drain contact portion in a second direction;
a first interlayer insulating film on the source/drain contact structure and covering a side wall of the source/drain via portion, an upper surface of the first interlayer insulating film being higher than an upper surface of the source/drain via portion;
an etching stop film extending along the upper surface of the first interlayer insulating film;
a second interlayer insulating film on the etching stop film; and
a connection wiring in the first interlayer insulating film and the second interlayer insulating film, the connection wiring being in contact with the upper surface of the source/drain via portion.

2. The semiconductor device of claim 1,
wherein the connection wiring includes a line portion and a protruding portion,
the line portion of the connection wiring is on the first interlayer insulating film and extends in a third direction, and
the protruding portion of the connection wiring protrudes from the line portion of the connection wiring in the second direction and is inside the first interlayer insulating film.

3. The semiconductor device of claim 2,
wherein side walls of the protruding portion of the connection wiring are in contact with the first interlayer insulating film.

4. The semiconductor device of claim 2,
wherein the first interlayer insulating film further includes an impurity accumulation region along side walls of the protruding portion of the connection wiring, and
the impurity accumulation region includes carbon (C) or titanium (Ti).

5. The semiconductor device of claim 1, wherein
the source/drain via portion includes a first portion and a second portion,
the second portion of the source/drain via portion is between the first portion of the source/drain via portion and the connection wiring,
the second portion of the source/drain via portion includes the upper surface of the source/drain via portion,
a width of the first portion of the source/drain via portion in the first direction decreases as it goes away from the source/drain pattern, and
a width of the second portion of the source/drain via portion in the first direction increases as it goes away from the source/drain pattern.

6. The semiconductor device of claim 1, wherein
the source/drain via portion includes a first portion and a second portion,
the second portion of the source/drain via portion is between the first portion of the source/drain via portion and the connection wiring, the second portion of the source/drain via portion includes the upper surface of the source/drain via portion,
a width of the first portion of the source/drain via portion in the first direction decreases as it goes away from the source/drain pattern, and
a width of the second portion of the source/drain via portion in the first direction is constant as it goes away from the source/drain pattern.

7. The semiconductor device of claim 1,
wherein the source/drain contact structure has a single conductive film structure.

8. The semiconductor device of claim 1,
wherein the source/drain contact structure includes a contact barrier film and a contact filling film on the contact barrier film, and
the contact filling film included in the source/drain contact portion and the source/drain via portion is an integral structure.

9. The semiconductor device of claim 1,
wherein the etching stop film includes aluminum oxide or aluminum nitride.

10. A semiconductor device comprising:
a source/drain pattern on a substrate;
a source/drain contact structure connected to the source/drain pattern;
a first interlayer insulating film on the source/drain contact structure, an upper surface of the first interlayer insulating film being higher than an upper surface of the source/drain contact structure;
a second interlayer insulating film on the first interlayer insulating film;
an etching stop film between the first interlayer insulating film and the second interlayer insulating film, and the etching stop film extending along the upper surface of the first interlayer insulating film; and
a connection wiring in the first interlayer insulating film and the second interlayer insulating film, the connection wiring being in contact with the source/drain contact structure, wherein
the connection wiring includes a line portion and a protruding portion,
the line portion extends in a first direction on the first interlayer insulating film,
the protruding portion protrudes from the line portion in a second direction,
the protruding portion of the connection wiring is in the first interlayer insulating film and the protruding portion of the connection wiring is in contact with the upper surface of the source/drain contact structure, and
the etching stop film does not extend along a boundary between the protruding portion of the connection wiring and the first interlayer insulating film.

11. The semiconductor device of claim 10,
wherein side walls of the protruding portion of the connection wiring are in contact with the first interlayer insulating film.

12. The semiconductor device of claim 10, wherein
the source/drain contact structure includes a source/drain contact portion and a source/drain via portion,
the source/drain contact portion extends in a third direction,
the source/drain via portion protrudes from the source/drain contact portion in the second direction, and
the source/drain via portion includes the upper surface of the source/drain contact structure.

13. The semiconductor device of claim 12, wherein
the source/drain via portion includes a first portion and a second portion,
the second portion of the source/drain via portion is between the first portion of the source/drain via portion and the connection wiring,
the second portion of the source/drain via portion includes an upper surface of the source/drain via portion,
a width of the first portion of the source/drain via portion in the first direction decreases as it goes away from the source/drain pattern, and
a width of the second portion of the source/drain via portion in the first direction increases as it goes away from the source/drain pattern.

14. The semiconductor device of claim 10,
wherein the first interlayer insulating film further includes an impurity accumulation region along side walls of the protruding portion of the connection wiring, and
the impurity accumulation region includes carbon (C) or titanium (Ti).

15. The semiconductor device of claim 10,
wherein the source/drain contact structure has a single conductive film structure.

16. The semiconductor device of claim 10,
wherein the etching stop film includes aluminum oxide or aluminum nitride.

17. A semiconductor device comprising:
a gate electrode extending in a first direction on a substrate;
a source/drain pattern on the substrate and disposed on at least one side of the gate electrode;
a source/drain contact structure connected to the source/drain pattern,
the source/drain contact structure including a source/drain contact portion and a source/drain via portion, the source/drain contact portion extending in the first direction, and the source/drain via portion protruding from the source/drain contact portion in a second direction;
a first interlayer insulating film on the source/drain contact structure and covering a side wall of the source/drain via portion, an upper surface of the first interlayer insulating film being higher than an upper surface of the source/drain via portion;
a gate contact in the first interlayer insulating film and connected to the gate electrode, an upper surface of the gate contact being higher than an upper surface of the source/drain contact structure;
a second interlayer insulating film on the first interlayer insulating film;
an etching stop film between the first interlayer insulating film and the second interlayer insulating film, the etching stop film extending along the upper surface of the first interlayer insulating film; and
a connection wiring in the first interlayer insulating film and the second interlayer insulating film, the connection wiring being in contact with the upper surface of the source/drain via portion, wherein
the connection wiring includes a line portion and a protruding portion,
the line portion extends in a third direction on the first interlayer insulating film,
the protruding portion protrudes from the line portion of the connection wiring in the second direction, and
the protruding portion of the connection wiring is in the first interlayer insulating film.

18. The semiconductor device of claim 17,
wherein the etching stop film is not on the side wall of the protruding portion of the connection wiring.

19. The semiconductor device of claim 17,
wherein the source/drain contact structure has a single conductive film structure.

20. The semiconductor device of claim 17,
wherein the source/drain via portion includes a first portion and a second portion,
the second portion of the source/drain via portion is between the first portion of the source/drain via portion and the connection wiring,
the second portion of the source/drain via portion includes the upper surface of the source/drain via portion,
a width of the first portion of the source/drain via portion in the first direction decreases as it goes away from the source/drain pattern, and
a width of the second portion of the source/drain via portion in the first direction increases as it goes away from the source/drain pattern.
